(19) United States
(12) Patent Application Publication
(10) Pub. No.: US 2025/0269405 A1
(43) Pub. Date: Aug. 28, 2025

(54) SENSOR STRUCTURE

(71) Applicant: TDK Electronics AG, Muenchen (DE)

(72) Inventors: Philipp Seebacher, Wien (AT); Mikel Gorostiaga Altuna, Graz (AT); Dominik Taferner, Preding (AT); Stefan Sax, Graz (AT); Michael Pirolt, Graz (AT); Patrick Swaschnig, Graz (AT)

(21) Appl. No.: 18/855,265

(22) PCT Filed: Mar. 2, 2023
(86) PCT No.: PCT/EP2023/055267

§ 371 Date: Oct. 8, 2024

(30) Foreign Application Priority Data
Apr. 14, 2022 (DE) 10 2022 109 302.6

(51) Int. Cl. B06B 1/06; G01N 29/24; G01N 29/32

(52) U.S. Cl. CPC B06B 1/0644; G01N 29/2437; G01N 29/32; G01N 2291/102

(57) ABSTRACT

In an embodiment a sensor structure for arrangement on a body includes a substrate in which at least one emitter and at least one receiver are integrated such that the substrate at least partially encloses the emitter and the receiver and only one emission surface of the emitter and only one detection surface of the receiver are free of the substrate.

### CROSS-REFERENCE TO RELATED APPLICATIONS

This patent application is a national phase filing under section 371 of PCT/EP2023/052267, filed Mar. 2, 2023, which claims the priority of German patent application 102022109302.6, filed Apr. 14, 2022, each of which is incorporated herein by reference in its entirety.

### TECHNICAL FIELD

A sensor structure is specified.

### BACKGROUND

Sensor structures are used, for example, for ultrasonic testing and/or structural monitoring of materials. In particular, ultrasonic testing or structural monitoring can be used to detect material defects in materials or homogeneous and inhomogeneous bodies. In ultrasonic testing, for example, mechanical waves with frequencies in an ultrasonic range are excited in the body to be tested. Material defects, for example, lead to scattering, diffraction and/or reflections of the mechanical waves. By detecting the scattered, diffracted and/or reflected mechanical waves, a structural condition and/or structural integrity of the body can be determined, for example.

The publication V. Giurgiutiu, “Structural health monitoring with piezoelectric wafer active sensors”, Academic Press, 2014, describes piezoelectric sensors for structural integrity monitoring.

The publication X. P. Qing et al, “Effect of adhesive on the performance of piezoelectric elements used to monitor structural health”, Int. Journal of adhesion & adhesives, 2006, describes the effect of adhesives on piezoelectric elements for structural integrity monitoring.

The publication V. Giurgiutiu and C. Soutis, “Enhanced composite integrity through structural health monitoring”, Appl. Compos. Mater., Springer 2012, describes how the integrity of safety-critical composite materials can be improved through the use of structural integrity monitoring techniques.

The publication U.S. Pat. No. 8,966,997 B2 describes a pressure-sensitive mat.

The publication US 2014/0090489 A1 describes a pressure-sensitive mat with several sensor types.

The publication EP 1944095 A2 describes a device, a system and a method for structural integrity monitoring.

The publication ES 2555683 T3 describes a sensor infrastructure with integrated electronics.

The publication CN 101365928 A describes a sensor and a system for structural integrity monitoring.

The publication EP 2548473 B1 describes a system for measuring humidity for use in a hospital bed.

The publication US 2011/0190761 A1 describes a neutral electrode with temperature measurement.

To excite mechanical waves in a body, for example, a piezo element is arranged on a surface of the body. In order to transmit the excitation energy of the piezo element to the body as efficiently as possible, the piezo element is, in particular, firmly attached to the body. The piezo element is made of a ceramic material, for example, and can therefore be brittle. In particular, the piezo element can be damaged and/or break when applied to a mechanically stressed body, such as a fiber composite material or a lithium-ion cell in an electric car, for example. Electrical contacts of the piezo element can also be damaged and/or break due to mechanical tension on the body. Furthermore, the piezo element's functionality can be impaired by environmental influences. Environmental influences include, for example, external mechanical forces, dust, moisture, temperature fluctuations and/or ultraviolet light.

### SUMMARY

Embodiments provide an improved sensor structure which is particularly robust and/or particularly easy to apply to a mechanically braced body.

The sensor structure for arrangement on a body comprises a substrate in which at least one emitter and at least one receiver are integrated in such a way that the substrate at least partially encloses the emitter and the receiver and only one emission surface of the emitter and only one detection surface of the receiver are free of the substrate. In particular, all surfaces of the emitter and the receiver, with the exception of the emission surface of the emitter and with the exception of the detection surface of the receiver, are at least partially covered by the substrate. For example, the substrate at least partially covers a rear surface and side surfaces of the receiver and/or the emitter, wherein the rear surface is opposite the emission surface or the detection surface and the side surfaces connect the rear surface to the emission surface or the detection surface.

The emitter and the receiver are preferably spatially separate elements. In other words, the sensor structure does not, for example, have an element that performs both a function of the emitter and a function of the receiver. Thus, the emitter and the receiver can be adapted and/or optimized in particular for the respective function. For example, the emitter and the receiver are designed differently.

For example, the sensor structure has exactly one emitter and exactly one receiver. Alternatively, the sensor structure can also comprise several emitters and/or several receivers. A number of emitters and/or receivers can be adapted to the body.

Alternatively or additionally, the emitter and the receiver can be designed as a single, common element. The common element thus assumes the functions of the emitter and receiver described below in particular.

Furthermore, the emitter and receiver can be interchangeable or interchangeable in their functions. For example, the emitter can be set up as a receiver, and vice versa. For example, the functions of the emitter and receiver can be swapped during operation of the sensor structure.

In particular, the substrate is designed to mechanically stabilize the sensor structure. Preferably, the substrate is flexible. In other words, the substrate comprises a soft material that can be bent with little force. For example, a modulus of elasticity of the substrate is at most 5 GPa. For example, the substrate comprises a silicone, a soft polymer such as polyurethane, or a foam-based material, or consists of one of these materials.

In particular, the substrate is designed to protect the emitter and receiver from environmental influences. For example, the substrate protects the emitter and receiver from dust, moisture, UV light, temperature fluctuations and/or external mechanical forces.

The emitter is set up to generate mechanical waves in the body and the receiver is set up to detect the mechanical waves in the body. The emitter is preferably set up to excite Lamb waves in the body. Lamb waves comprise, for example, a combination of transverse and longitudinal waves in the body, wherein the body is deformed both longitudinally and transversely to a direction of propagation of the mechanical wave. Lamb waves, for example, have an approximately uniform distribution over a thickness of the body. The thickness here refers to a spatial expansion of the body in a direction perpendicular to the direction of propagation, with the mechanical waves propagating in particular from the emitter to the receiver. Thus, the structural condition of the body can be advantageously determined over the entire thickness of the body.

The emitter and/or the receiver are preferably sound transducers. For example, the emitter converts an electrical input signal into a mechanical wave, while the receiver converts a mechanical wave into an electrical output signal.

The mechanical waves preferably have a frequency in an ultrasonic range. In particular, the ultrasonic range comprises frequencies above a human hearing frequency range. For example, the ultrasonic range comprises frequencies between 20 kHz and 1 GHz inclusive. The mechanical waves may also have frequencies within the human hearing frequency range. For example, the mechanical waves have a frequency of less than 20 kHz. The frequency of the mechanical waves can advantageously be adapted to the characteristics of the body.

According to a further embodiment of the sensor structure, the emitter is arranged on a first side of the substrate and the receiver is arranged on a second side of the substrate, which is opposite the first side. In particular, the emitter and the receiver may be arranged on the same side of the substrate, or on different sides of the substrate. For example, the emission surface of the emitter and the detection surface of the receiver may have the same or different orientation. In other words, a surface normal of the emission surface and a surface normal of the detection surface may face in the same or in different directions. For example, an angle between the surface normals of the emission surface and the detection surface is about 0°, about 90°, or about 180°, wherein the angle is changeable within a certain range by the flexible configuration of the substrate.

For example, the emission surface is arranged on an underside of the substrate, while the detection surface is arranged on an upper side of the substrate, or vice versa. The upper side and the underside side are opposite main surfaces of the substrate. In a top view of the main surface of the substrate, the emitter and the receiver can, for example, be arranged one above the other or offset from each other.

A plurality of emitters and/or a plurality of receivers can also be arranged on any side of the substrate. For example, emitters and/or receivers are arranged on both the underside and the upper side of the substrate.

According to a further embodiment of the sensor structure, the emitter and the receiver are laterally spaced apart. Here and hereinafter, lateral refers to a main direction of extension of the substrate. In particular, the substrate extends in lateral directions and has a thickness in a vertical direction, the vertical direction being perpendicular to the lateral directions. The thickness of the substrate is preferably less than the lateral extent of the substrate. For example, a lateral distance between the emitter and the receiver is greater than a lateral extent of the emitter and/or a lateral extent of the receiver.

According to a further embodiment of the sensor structure, the emitter is only set up to generate mechanical waves and the receiver is only set up to detect mechanical waves. In other words, the emitter is set up exclusively for generating the mechanical waves and not for detecting the mechanical waves, while the receiver is set up exclusively for detecting the mechanical waves and not for generating the mechanical waves.

According to a further embodiment of the sensor structure, a modulus of elasticity of the substrate is smaller than a modulus of elasticity of the body. In other words, the substrate is softer than the body. In particular, the mechanical waves between the emitter and the receiver preferentially propagate through the body. For example, transmission of the mechanical waves from the emitter to the receiver through the substrate is hindered or suppressed by the small modulus of elasticity of the body. For example, the modulus of elasticity of the body is greater than the modulus of elasticity of the substrate by at least a factor of 10.

If the modulus of elasticity of the body is greater than the modulus of elasticity of the substrate by at least a factor of 10, for example, only a negligible proportion of the mechanical waves generated by the emitter will propagate via the substrate to the receiver. In particular, the mechanical waves are essentially transmitted from the emitter to the receiver via the body. Ultrasonic waves that propagate from the emitter via the substrate to the receiver cannot contribute to testing the structural integrity of the body and represent, for example, an interference signal. The substrate is therefore preferably designed to prevent and/or at least strongly attenuate such waves.

According to a further embodiment of the sensor structure, the substrate comprises a damping element arranged between the emitter and the receiver and having a lower modulus of elasticity than the substrate. In particular, the damping element is arranged to impede or reduce a direct transmission of mechanical waves between the emitter and the receiver through the substrate. For example, the damping element is formed as a section of the substrate that has a softer material than the substrate. The modulus of elasticity of the substrate is, for example, greater than the modulus of elasticity of the damping element by at least a factor of 2.

According to a further embodiment of the sensor structure, the damping element extends completely over a cross-sectional area of the substrate. The damping element can also extend only partially over the cross-sectional area of the substrate. In particular, the cross-sectional area refers to an area extending through the substrate, wherein the emitter is arranged on one side of the cross-sectional area, while the receiver is arranged on another side of the cross-sectional area. In other words, the cross-sectional area separates the substrate into two separate areas, wherein the emitter is disposed in one of the two areas and the receiver is disposed in another of the two areas. A damping element extending completely over the cross-sectional area of the substrate thus separates the substrate into two separate parts, which are connected to each other via the damping element. As a result, the direct transmission of mechanical waves between the emitter and the receiver via the substrate can be greatly reduced.

According to a further embodiment of the sensor structure the emitter and/or the receiver have a piezo element. The piezo element of the emitter deforms in particular when an electrical voltage is applied. For example, the piezo element of the receiver generates an electrical voltage when the piezo element is mechanically deformed by an external mechanical force.

The piezo element comprises, for example, a piezo crystal, a polycrystalline piezo ceramic or a piezoelectric polymer, such as polyvinylidene fluoride (PVDF for short). In particular, the piezo element is configured to work as a sound transducer that converts an electrical signal into a mechanical wave, or vice versa.

The piezo element has, for example, a platelet shape or a wedge shape, whereby a lateral expansion is in particular greater than a vertical expansion of the piezo element. In a lateral plane, the piezo element has, for example, a circular, oval, square, rectangular or polygonal cross-sectional area.

The piezo element is made, for example, from a single piece of piezo crystal or piezo ceramic. Alternatively or additionally, the piezo element can have a large number of piezoelectric sub-elements embedded in a matrix material. The matrix material is, for example, a plastic, in particular an epoxy.

According to a further embodiment of the sensor structure, a thickness of the emitter and/or a thickness of the receiver is at most 1 mm and/or a thickness of the sensor structure is at most 3 mm. The thickness here and in the following refers to a spatial expansion in the vertical direction. Due to a low thickness, the sensor structure has in particular an advantageously high flexibility.

According to a further embodiment of the sensor structure, flexible electrical wiring is integrated into the substrate for making electrical contact with the emitter and/or the receiver. The flexible electrical wiring comprises, for example, metallic conductor tracks or a coaxial cable. In particular, the flexible electrical wirings are arranged such that they are not damaged or break when the substrate is bent. Preferably, the flexible electrical wiring is at least partially enclosed by the substrate. For example, the substrate is designed to provide electrical insulation for the flexible electrical wiring.

The flexible electrical wiring is electrically connected to the emitter and/or the receiver, for example via a soldered connection or with an electrically conductive adhesive.

According to a further embodiment, the sensor structure additionally has at least one sensor integrated into the substrate. The sensor is set up to measure at least one operating parameter. For example, the sensor is a humidity sensor, a temperature sensor and/or a pressure sensor.

Here and in the following, “integrated” means that the sensor is at least partially enclosed by the substrate. In particular, at least two different surfaces or sides of the sensor are at least partially covered by the substrate. Several sensors can also be integrated into the substrate. In particular, the substrate is designed to protect sensors integrated into the substrate from environmental influences.

Together with the emitter and the receiver, the humidity sensor, the temperature sensor and/or the pressure sensor are set up, for example, to monitor a condition of the body. For example, the emitter, the receiver, the humidity sensor, the temperature sensor and/or the pressure sensor are connected to evaluation electronics. The evaluation electronics are configured, for example, to generate a warning and/or change operating parameters when predefined threshold values are reached.

According to a further embodiment of the sensor structure, the substrate encloses the emitter and the receiver in such a way that only one emission surface of the emitter and only one detection surface of the receiver are free of the substrate. In particular, all surfaces of the emitter and all surfaces of the receiver, with the exception of the emission surface of the emitter and with the exception of the detection surface of the receiver, are covered by the material of the substrate. The mechanical waves are preferably coupled out from the emitter via the emission surface. Furthermore, the mechanical waves are preferably coupled into the receiver via the detection surface.

During operation of the sensor structure, the emission surface of the emitter and the detection surface of the receiver are preferably reversibly or irreversibly connected to the body, either directly or via a connecting means. Thus, the emitter and the receiver are in particular covered on all sides either by the substrate or by the body. During operation of the sensor structure, the emitter and the receiver are therefore advantageously protected from environmental influences.

For example, the emission surface of the emitter and/or the detection surface of the receiver is flush with the substrate. In other words, side surfaces of the emitter and/or the receiver are completely covered by the substrate, so that the emission surface and/or the detection surface forms a plane with a surface of the substrate. This advantageously allows direct contact to be established between the body and the emitter and/or the receiver, while protecting the emitter and/or the receiver from environmental influences.

Alternatively or additionally, the emitter and/or the receiver can also protrude from the substrate. This means that side surfaces of the receiver and/or the emitter are only partially covered by the substrate. This allows, for example, better contact to be established between the body and the emission surface of the emitter and/or the detection surface of the receiver.

Furthermore, the substrate can be compressed by mechanically bracing the sensor structure with the body, for example. As a result, the substrate applied to the body is deformed, for example, so that the side surfaces of the emitter and/or the receiver are completely covered by the substrate. Thus, the emitter and/or the receiver are advantageously completely enclosed by the substrate and the body due to the mechanical tension.

According to a further embodiment of the sensor structure, a carrier foil is applied to the emission surface of the emitter and/or to the detection surface of the receiver. The carrier foil is designed, for example, to protect the emission surface and/or the detection surface. In particular, the carrier foil protects the emitter and/or the receiver from moisture, dust, mechanical forces and/or ultraviolet light, for example. For example, the carrier foil has a glass, a metal or a polymer, or consists of one of these materials.

According to another embodiment of the sensor structure the carrier foil is set up to change a resonant frequency of the emitter and/or the receiver. For example, the carrier foil increases an inertial mass of the emitter and/or the receiver. Thus, in particular, a resonant frequency of the emitter and/or the receiver can be lowered. For example, a resonant frequency of the emitter and/or the receiver can be adapted to the structural properties of the body.

According to a further embodiment of the sensor structure, the thickness of the carrier foil is at most 500 μm. The thickness here refers to a spatial expansion of the carrier foil in a direction perpendicular to the emission surface of the emitter or perpendicular to the detection surface of the receiver. In particular, a thin carrier foil with a thickness of, for example, at most 500 μm is advantageous for good mechanical coupling between the body and the emitter and/or the receiver. For example, the attenuation of the mechanical waves by the thin carrier foil is advantageously small, while the attenuation may also depend on the material of the carrier foil.

According to a further embodiment of the sensor structure, the emitter and/or the receiver has an electrical shielding element. In particular, the electrical shielding element is configured to shield and/or protect the emitter and/or the receiver from electromagnetic interference. For example, the shielding covers all surfaces of the emitter and/or the receiver with the exception of the emission surface and/or the detection surface. In particular, the shielding element is arranged between the substrate and the receiver and/or between the substrate and the emitter.

Alternatively or additionally, the shielding element can also cover the emission surface of the emitter and/or the detection surface of the receiver. In this way, the shielding element also assumes the function of the carrier foil, for example. In this case, all surfaces of the emitter and/or the receiver are covered and/or enclosed by the shielding element, with the flexible electrical wiring for electrical contacting of the emitter and/or the receiver being routed in particular through the shielding element.

The shielding element comprises an electrically conductive material or consists of an electrically conductive material. The electrically conductive material is, for example, a metal, in particular copper. The shielding element is, for example, a metal foil, a metallic mesh, or has metallic wires or a metallic foam. In particular, an electrically insulating structure is arranged between the shielding element and the flexible electrical wiring and the electrodes of the emitter and receiver. The shielding element can also be designed to provide mechanical protection for the receiver and/or the emitter.

According to a further embodiment, the sensor structure has evaluation electronics that are electrically connected to the emitter and the receiver and are set up to determine a structural condition of the body from the detected mechanical waves. The evaluation electronics can also be electronically connected to one or more additional sensors that are integrated into the substrate of the sensor structure. In particular, the additional sensor is set up to determine a condition of the body. For example, the additional sensor is a humidity sensor, a temperature sensor and/or a pressure sensor.

The evaluation electronics can be attached to the substrate, integrated into the substrate or spatially separated from the substrate. Spatial separation of the evaluation electronics from the substrate is particularly advantageous if only a small installation space is available in which the substrate is to be arranged on the body. For example, the evaluation electronics are connected to the emitter and the receiver via the flexible electrical wiring.

Furthermore, an arrangement is disclosed. In particular, the arrangement comprises a sensor structure described herein and a body to which the sensor structure is applied. All features of the sensor structure are also disclosed for the arrangement, and vice versa.

According to one embodiment, the arrangement comprises a sensor structure as described herein and a body, wherein the sensor structure is permanently or reversibly bonded to the body. For example, the sensor structure is permanently, i.e. irreversibly, bonded to the body. In particular, an adhesive layer is arranged between a surface of the body and the emission surface of the emitter and the detection surface.

The adhesive layer is as thin and as hard as possible. In particular, the adhesive layer is configured to provide good mechanical coupling and thus efficient transmission of the mechanical waves between the sensor structure and the body. For example, the adhesive layer has a thickness of at most 10 μm.

Alternatively, the sensor structure can also be reversibly connected to the body. For example, a coupling gel is arranged between the sensor structure and the body. In particular, the coupling gel can be easily removed. Furthermore, the sensor structure can be mechanically clamped to the body. In particular, the clamping is reversible and the sensor structure can be removed from the body after a measurement process, for example.

For example, the body has a mechanical pretension. The mechanical pretension is, in particular, a mechanical tension of the body that is present with or without an external force. In other words, tensile forces and/or compressive forces, for example, act within the body with or without external force. The mechanical pretension can be used, for example, to adjust the behavior of the body under external force.

In the case of lithium-ion cells in electric cars, for example, the mechanical pretension serves to increase the service life of the cells. In particular, the sensor structure described here can be mechanically pretensioned together with the cells and monitor the function of the cells during operation. Advantageously, the sensor structure remains functional despite the load caused by the mechanical tensioning.

According to another embodiment of the arrangement, the body comprises a plurality of battery cells and/or a fiber composite material. For example, the body is a battery of an electrically powered vehicle, wherein the battery comprises a plurality of battery cells in a housing. In particular, the sensor structure may be disposed between the battery cells and the housing. For example, the sensor structure is configured to determine a structural condition of the battery cells. Furthermore, the sensor structure can be set up as a spacer between the battery cells and the housing. This protects the battery cells from direct contact with the housing.

The fiber composite material comprises, for example, a multitude of fabric mats that comprise glass fibers and/or carbon fibers. In particular, the fabric mats are bonded together with a synthetic resin. The glass fibers or carbon fibers can also be randomly distributed in a matrix material, such as a plastic. For example, the fiber composite material is a glass-fiber reinforced plastic (GFRP for short). The sensor structure can, for example, be permanently arranged between fabric mats of the fiber composite material. Alternatively or additionally, the sensor structure can also be laminated onto the fiber composite material.

Furthermore, the sensor structure can be designed to protect the body from environmental influences, such as mechanical forces, dust, moisture, UV light and/or rapid temperature fluctuations.

Furthermore, a method for operating a sensor structure is disclosed. In particular, the method is designed for operating a sensor structure described herein. All features of the sensor structure are also disclosed for the method for operating a sensor structure, and vice versa.

According to an embodiment of the method for operating a sensor structure, a sensor structure described herein is arranged on the body in such a way that the emission surface of the emitter and the detection surface of the receiver are in contact with the body. For example, the sensor structure is clamped onto the body in such a way that the detection surface of the receiver and the emission surface of the emitter are in direct contact with a surface of the body. A coupling gel, a wax or an adhesive can also be arranged between the emission surface of the emitter and the body and between the detection surface of the receiver and the body, for example. The coupling gel, the wax or the adhesive are designed in particular to establish good mechanical contact between the sensor structure and the body for the transmission of mechanical waves.

Alternatively or additionally, the sensor structure can be bonded to the body or permanently connected in some other way. In particular, the emission surface of the emitter and the detection surface of the receiver can be permanently bonded to a surface of the body.

According to a further embodiment of the method, the emitter excites mechanical waves in the body during operation and the receiver detects the mechanical waves in the body. For example, the emitter converts the electrical input signal into mechanical waves that propagate in the body. The receiver detects the mechanical waves propagating in the body and converts them, for example, into the electrical output signal. The emitter and/or the receiver can also be set up to excite and detect the mechanical waves.

According to a further embodiment of the method, a structural state of the body is determined from the detected mechanical waves. For example, evaluation electronics can determine propagation times of various scattered fractions of the mechanical wave between a time of emission at the emitter and a time of detection at the receiver. This, in particular, makes it possible to detect material defects in the body and thus determine the structural integrity of the body.

According to a further embodiment of the method, the emitter generates lateral, vertical and/or radial modes of vibration during operation. For example, an electrical input signal from the emitter is converted into a lateral, vertical and/or radial deformation of the emitter. A radial deformation is, for example, a uniform deformation in all lateral directions. Depending on the type of deformation of the emitter, different mechanical waves can be excited in the body, for example. Preferably, Lamb waves are excited in the body, which are distributed evenly over the thickness of the body.

### BRIEF DESCRIPTION OF THE DRAWINGS

Further advantageous embodiments and further embodiments of the sensor structure and of the arrangement and method for operating a sensor structure result from the exemplary embodiments described below in conjunction with the figures.

FIG. 1 shows a schematic sectional view of a sensor structure according to an exemplary embodiment;

FIGS. 2 and 3 show schematic perspective views of a sensor structure according to various exemplary embodiments;

FIG. 4 shows a schematic sectional view of a sensor structure according to a further exemplary embodiment;

FIGS. 5, 6 and 7 show schematic perspective views of an arrangement according to an exemplary embodiment;

FIGS. 8 and 9 show schematic representations of a flexible electrical wiring according to various examples;

FIGS. 10 and 11 show schematic sectional views of an arrangement according to various exemplary embodiments;

FIG. 12 shows measurement results of the impedance of an emitter or receiver as a function of frequency;

FIGS. 13 and 14 show schematic sectional views of a sensor structure according to further exemplary embodiments; and

FIG. 15 shows a schematic sectional view of an arrangement according to a further exemplary embodiment.

Elements that are identical, similar or have the same effect are marked with the same reference sign in the figures. The figures and the proportions of the elements shown in the figures should not be considered to be true to scale. Rather, individual elements may be shown exaggeratedly large or small for better visualization and/or understanding.

### DETAILED DESCRIPTION OF ILLUSTRATIVE EMBODIMENTS

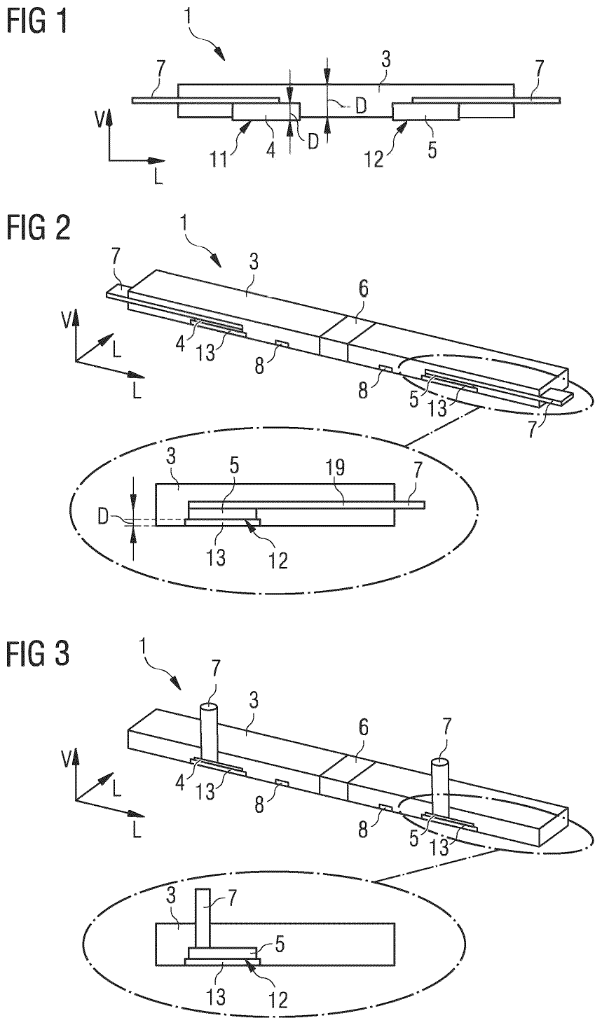

The exemplary embodiment of the sensor structure 1 in FIG. 1 has a substrate 3, an emitter 4 and a receiver 5. The substrate 3 comprises a soft polymer, for example polyurethane, in which the emitter 4 and the receiver 5 are integrated. In particular, the substrate 3 at least partially encloses surfaces of the emitter 4 and the receiver 5, with only an emission surface 11 of the emitter 4 and a detection surface 12 of the receiver 5 remaining free of the substrate. A thickness D of the emitter 4 and the receiver 5 is at most 1 mm, while the thickness D of the sensor structure 1 is at most 3 mm.

Both the emitter 4 and the receiver 5 comprise a piezo element. The piezo element of the emitter 4 is set up to convert an electrical input signal into mechanical waves. The piezo element of the receiver 5 is set up to convert mechanical waves into an electrical output signal. The emitter 4 and the receiver 5 are spaced apart from each other in the lateral direction L.

Flexible electrical wiring 7 is integrated into the substrate 3. The flexible electrical wiring 7 is configured for electrically contacting the emitter 4 and the receiver 5. Preferably, the flexible electrical wiring 7 has the same or a lower modulus of elasticity than the substrate 3. This means that the flexible electrical wiring 7 is advantageously not damaged when the sensor structure 1 is subjected to a bending load, for example.

In particular, the sensor structure 1 is applied to a body 2 (not shown here, see e.g. FIG. 5) whose structural condition is to be determined. During operation of the sensor structure 1, mechanical waves are generated by the emitter 4, which propagate through the body 2 and are detected by the receiver 5. In particular, the structural integrity of the body 2 can be checked by evaluating the mechanical waves detected by the receiver.

The embodiment example of the sensor structure 1 in FIG. 2 has a damping element 6 in addition to the sensor structure 1 described in connection with FIG. 1. The damping element 6 is arranged between the emitter 4 and the receiver 5 and has a smaller modulus of elasticity than the substrate 3. Thus, the damping element 6 hinders and/or reduces a direct transmission of the mechanical waves from the emitter 4 to the receiver 5 through the substrate 3.

Furthermore, the sensor structure 1 has carrier foils 13, which are applied to the emission surface 11 of the emitter 4 and to the detection surface 12 of the receiver 5. The carrier foils 13, for example, comprise a hard polymer and protect the receiver 4 and the emitter 5 from environmental influences, such as dust, moisture or mechanical forces. The carrier foils 13 are also configured to adjust a resonant frequency of the emitter 4 and the receiver 5. A thickness D of the carrier foil 13 is in particular at most 500 micrometers.

Flexible electrical wiring 7 comprises conductor tracks 19 that are integrated into the substrate 3 and extend in a lateral direction L through the substrate 3. Alternatively or additionally, the flexible electrical wiring 7 can also extend in a vertical direction V.

The sensor structure 1 has two integrated sensors 8, such as a humidity sensor, a temperature sensor and/or a pressure sensor. The sensor structure 1 can also have one or more than two integrated sensors 8. Electrical lines for electrical contacting of the further sensors 8 are not shown for clarity.

In contrast to the sensor structure 1 in FIG. 2, the sensor structure 1 in FIG. 3 has flexible electrical wiring 7, which is in the form of coaxial cables and extends through the substrate 3 in the vertical direction V. Alternatively or additionally, the coaxial cables can also be routed in the lateral direction L.

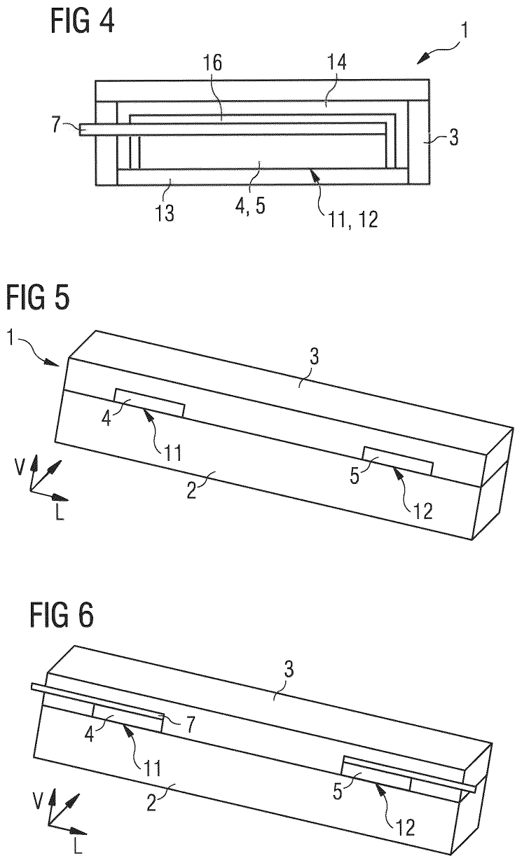

Compared to the sensor structure 1 described in connection with FIG. 2, the exemplary embodiment of the sensor structure 1 in FIG. 4 additionally has an electrical shielding element 14. The electrical shielding element 14 is arranged between the substrate 3 and the emitter 4 and/or the receiver 5. The electrical shielding element 14 is designed to protect the emitter 4 and/or the receiver 5 from electromagnetic interference and comprises a metallic foil, for example made of copper. In addition, the electrical shielding element 14 can protect the emitter 4 and/or the receiver 5 from the effects of mechanical forces.

An electrical insulation 16 is arranged between the electrical shielding element 14 and the emitter 4 and/or the receiver 5. The electrical insulation protects the emitter 4 and/or the receiver 5 in particular from electrical short circuits caused by the electrically conductive electrical shielding element 14.

The exemplary embodiment in FIG. 5 shows an arrangement comprising a body 2 with a sensor structure 1 arranged thereon. The sensor structure 1 is set up in particular to determine a structural state of the body 2. For example, the body 2 is a battery of an electrically powered vehicle or a fiber composite material.

A lateral extension of the sensor structure 1 is adapted in particular to a lateral extension of the body 2. The sensor structure 1 comprises a substrate 3 with an integrated emitter 4 and an integrated receiver 5. An emission surface 11 of the emitter 4 and a detection surface 12 of the receiver 5 are arranged on a surface of the body 2. For example, the sensor structure 1 is glued or clamped to the body 2.

Compared to the arrangement described in connection with FIG. 5, the exemplary embodiment of the arrangement in FIG. 6 additionally has flexible electrical wiring 7, which is set up for electrical contacting of the emitter 4 and the receiver 5. The flexible electrical wiring 7 is integrated into the substrate 3 of the sensor structure 1 and extends in the lateral direction L.

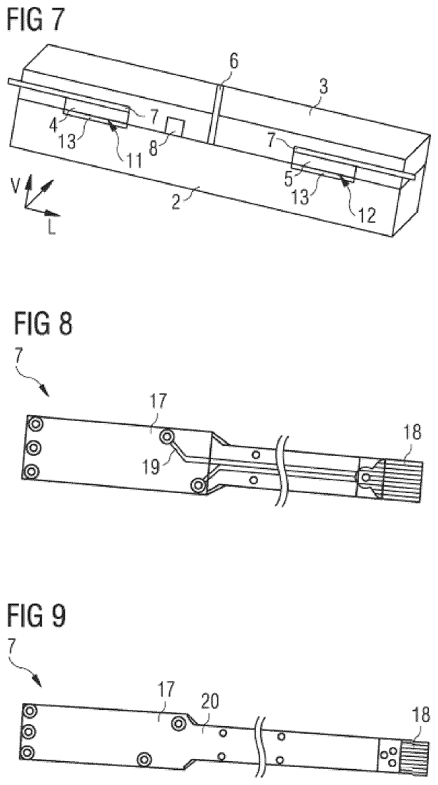

In comparison with the arrangement described in connection with FIG. 6, the exemplary embodiment of the arrangement in FIG. 7 additionally has carrier foils 13, which are arranged on the emission surface 11 of the emitter 4 and on the detection surface 12 of the receiver 5. Furthermore, the arrangement has a damping element which is arranged in the substrate 3 between the emitter 4 and the receiver 5.

FIG. 8 shows an example of a flexible electrical wiring 7 comprising metallic conductor tracks 19. The flexible electrical wiring 7 has a first connection area 17 for making electrical contact with the emitter 4 (not shown) or the receiver 5 (not shown). Furthermore, the flexible electrical wiring 7 has a second connection area 18, which is configured, for example, for electrical contacting of evaluation electronics 15 (not shown). The flexible electrical wiring has, for example, a thickness of at most 200 μm.

FIG. 9 shows another example of a flexible electrical wiring 7. In addition to the example described in connection with FIG. 8, the flexible electrical wiring 7 has one or more shielding layers 20 which are arranged to protect the flexible electrical wiring 7 from electromagnetic interference.

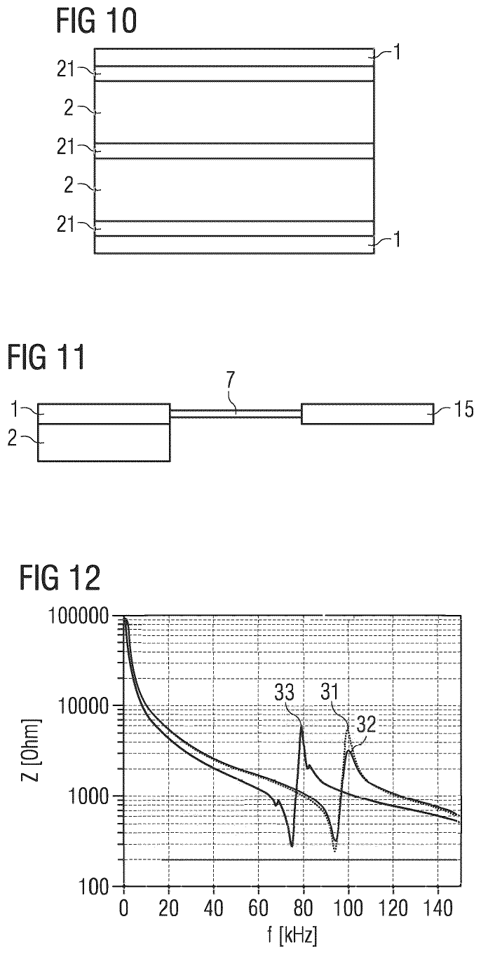

The exemplary embodiment of the arrangement in FIG. 10 has a body 2 comprising at least two layers, between which an adhesive layer 21 is arranged. For example, the body 2 is a fiber composite material. A sensor structure 1 is applied to opposite surfaces of the body 2, each of which is permanently bonded to the body 2 via an adhesive layer 21. Each sensor structure 1 has an emitter 4 and a receiver 5. In particular, the sensor structures 1 are also designed to protect the body 2, for example from moisture or mechanical forces. Alternatively, the sensor structures 1 can also be reversibly applied to the body 2, with, for example, a coupling gel being arranged between the body 2 and the sensor structures 1.

FIG. 11 shows an arrangement according to an exemplary embodiment that comprises a sensor structure 1, a body 2 and evaluation electronics 15. The sensor structure 1 is configured together with the evaluation electronics 15 to determine a structural state of the body 2 and is connected to the evaluation electronics 15 via a flexible electrical wiring 7. The evaluation electronics 15 is spatially separated from the sensor structure 1.

For example, the evaluation electronics 15 provides an electrical input signal for the sensor structure 1, which is converted into mechanical waves by the sensor structure 1. Mechanical waves detected by the sensor structure 1 are converted into an electrical output signal, which is analyzed by the evaluation electronics 15.

FIG. 12 shows measurement results of an impedance Z of an emitter 4 comprising a piezoelectric element. In particular, the impedance Z of the piezoelectric element is shown as a function of a frequency f of an electrical input signal applied to the piezoelectric element. The impedance Z exhibits a resonance at which the impedance Z changes within a small frequency interval, for example by an order of magnitude. The frequency f at which the resonance occurs depends in particular on a geometric structure and a mass of the piezo element.

The first curve 31 shows the impedance Z of a piezo element without a substrate 3, without a flexible electrical wiring 7 applied to it and without a carrier foil 13. In this case, the resonance occurs at a frequency f of approximately 95 kHz.

The second curve 32 shows the impedance Z of the same piezo element with a flexible electrical wiring 7 applied to it, which is integrated into a substrate 3. In particular, the resonant frequency does not change significantly as a result.

The third curve 33 shows the impedance Z of the same piezo element with a flexible electrical wiring 7 applied thereto and with a carrier foil 13 applied thereto, the piezo element being integrated into a substrate 3. In particular, the carrier foil 13 increases an inertial mass of the piezo element. This lowers the resonant frequency, which in this case occurs at approximately 75 kHz. The carrier foil thus shifts the resonant frequency in this example by approximately 20 kHz.

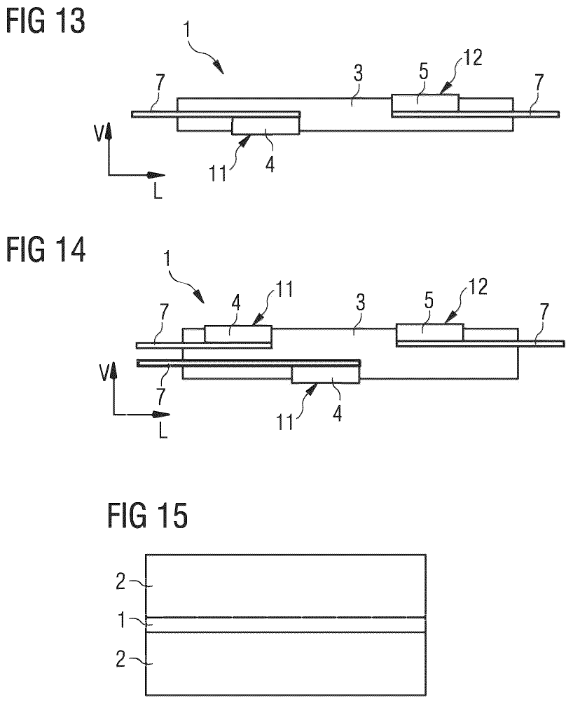

Compared to the sensor structure 1 described in connection with FIG. 1, the exemplary embodiment of the sensor structure 1 in FIG. 13 has a emitter 4 and a receiver 5 arranged on opposite sides of the substrate 3. The sensor structure 1 is designed, for example, to be arranged within a body 2 (see, for example, FIG. 15).

Compared to the sensor structure 1 described in connection with FIG. 13, the exemplary embodiment of the sensor structure 1 in FIG. 14 has a second emitter 4 which is arranged on the same side of the substrate 3 as the receiver 5, while the first emitter 4 is arranged on an opposite side of the substrate 3. Instead of the second emitter 4, for example, a second receiver 5 can also be arranged in the substrate 3.

The sensor structure 1 may also have a plurality of emitters 4 and/or a plurality of receivers 5. For example, the sensor structure 1 has an array of receivers. For example, the emitters 4 may be arranged on one side and the receivers 5 on the opposite side of the substrate 3, or both emitters 4 and receivers 5 may be arranged on both opposite sides of the substrate 3.

The exemplary embodiment of the arrangement in FIG. 15 has a body 2 comprising at least two layers between which a sensor structure 1 is arranged. For example, the body 2 is a fiber composite material. In particular, the sensor structure 1 is a sensor structure 1 according to one of the exemplary embodiment in FIGS. 13 and 14. Thus, the sensor structure 1 can advantageously monitor both layers of the body 2. The sensor structure 1 can have at least one emitter 4 and at least one receiver 5 on its upper side and on its lower side, respectively.

The arrangement shown in FIG. 15 can also be combined with the arrangement shown in FIG. 10, so that sensor structures 1 are arranged both inside the body 2 and on surfaces of the body 2. For example, the sensor structure 1 within the body has a plurality of emitters 4 on both opposite sides of the substrate 3, while the sensor structures 1 on the surfaces of the body 2 have a plurality of receivers 5, or vice versa.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

1.-17. (canceled)

18. A sensor structure for arrangement on a body, the sensor structure comprising:
a substrate in which at least one emitter and at least one receiver are integrated such that the substrate at least partially encloses the emitter and the receiver and only one emission surface of the emitter and only one detection surface of the receiver are free of the substrate.

19. The sensor structure according to claim 18, wherein the emitter is configured to generate mechanical waves in the body, and wherein the receiver is configured to detect the mechanical waves in the body.

20. The sensor structure according to claim 18, wherein the emitter is arranged on a first side of the substrate and the receiver is arranged on a second side of the substrate opposite the first side.

21. The sensor structure according to claim 18, wherein the emitter and the receiver are laterally spaced apart.

22. The sensor structure according to claim 18, wherein the emitter is configured to generate mechanical waves only and the receiver is configured to detect the mechanical waves only.

23. The sensor structure according to claim 18, wherein a modulus of elasticity of the substrate is less than a modulus of elasticity of the body.

24. The sensor structure according to claim 18, wherein the substrate has a damping element, which is arranged between the emitter and the receiver, and wherein the damping element has a lower modulus of elasticity than the substrate.

25. The sensor structure according to claim 24, wherein
the damping element extends completely over a cross-sectional area of the substrate.

26. The sensor structure according to claim 18, wherein the emitter and/or the receiver comprises a piezo element.

27. The sensor structure according to claim 18, further comprising flexible electrical wiring for electrical contacting of the emitter and/or the receiver is integrated into the substrate.

28. The sensor structure according to claim 18, further comprising at least one sensor integrated in the substrate.

29. The sensor structure according to claim 18, further comprising a carrier foil located at the emission surface of the emitter and/or at the detection surface of the receiver.

30. The sensor structure according to claim 29, wherein
the carrier foil is configured to change a resonant frequency of the emitter and/or the receiver.

31. The sensor structure according to claim 18, wherein the emitter and/or the receiver comprises an electrical shielding element.

32. An arrangement comprising:
the sensor structure according to claim 18 and the body,
wherein the sensor structure is permanently or reversibly connected to the body.

33. The arrangement according to claim 32, wherein
the body comprises a plurality of battery cells and/or a fiber composite material.

34. A method for operating the sensor structure according to claim 18, wherein the emission surface of the emitter and the detection surface of the receiver are in contact with the body, the method comprising:
exciting, by the emitter, mechanical waves in the body;
detecting, by the receiver, the mechanical waves in the body; and
determining a structural state of the body from the detected mechanical waves.

35. The method according to claim 34, wherein the emitter generates lateral, vertical and/or radial modes of vibration.
